(19) United States
(12) Patent Application Publication
(10) Pub. No.: US 2006/0163989 A1
(43) Pub. Date: Jul. 27, 2006

(54) Blue color filter, and organic electroluminescent device using the same

(76) Inventors: Koji Kawaguchi, Nagano (JP); Ryoji Kobayashi, Nagano (JP); Kenya Sakurai, Nagano (JP)

Correspondence Address: RABIN & Berdo, PC, 1101 14TH STREET, NW, SUITE 500, WASHINGTON, DC, 20005, US

(21) Appl. No.: 10/519,448

(22) PCT Filed: Jun. 30, 2003
(86) PCT No.: PCT/JP03/08279

§ 371 Date: Dec. 6, 2005

(30) Foreign Application Priority Data
Jul. 10, 2002 (JP) 2002-201337

(51) Int. Cl. H01L 51/50; H05B 33/00; C09K 11/06

(52) U.S. Cl. 313/112; 252/301.35; 428/690; 428/917; 313/504; 313/506; 257/98

(57) ABSTRACT

A blue color filter contains a first colorant represented by structural formula (1) in the specification and a binder resin, and also contain a second colorant that absorbs fluorescence from the first colorant and does not have a fluorescence maximum in a visible wavelength region, whereby the blue color filter is suitable for an organic EL (electroluminescent) display for which the purity of the blue color and the transmissivity are high and the contrast is good.

### CROSS REFERENCE TO RELATED APPLICATION

The present application incorporates herein by reference the entire disclosure and contents of the corresponding PCT application PCT/JP2003/08279, filed Aug. 15, 2003. Also incorporated by reference are the entire disclosure and contents of the earlier corresponding Japanese application JP PA 2002-055275.

### TECHNICAL FIELD

The invention relates to a blue color filter, and an organic electroluminescent (hereinafter abbreviated to ‘organic EL’) device using the same, for use in a display of mobile terminal equipment, industrial measuring equipment or the like.

### BACKGROUND ART

As one method of making organic EL displays be multi-color or full-color, a color conversion method in which fluorescent materials that absorb light in the emission region of an organic light emitter and then emit fluorescence in the visible region are used in filters has been disclosed in Japanese Patent Application Laid-open No. 3-152897, Japanese Patent Application Laid-open No. 5-258860, and so on. According to this method, the color of the light emitted by the organic light emitter is not limited to being white, and hence an organic light emitter having a higher brightness can be used as a light source; for example, a color conversion method in which an organic light emitter that emits blue light is used, and the blue light is subjected to wavelength conversion into green light and red light is described in Japanese Patent Application Laid-open No. 3-152897, Japanese Patent Application Laid-open No. 8-286033, and Japanese Patent Application Laid-open No. 9-208944. If fluorescent color-converting films containing such fluorescent colorants are patterned with high detail onto a transparent supporting substrate, then a full-color luminescent-type display can be constructed even if low-energy light such as near ultraviolet light or visible light from an organic light emitter is used.

In an organic EL device that uses the color conversion method and has color filters, color-converting filters and an organic light emitter as constituent elements thereof, color filters produced using a pigment dispersion method are generally used in the case that heat resistance is required during the color display manufacturing process, and weather resistance and highly detailed pixels are required when using the display; fine dispersions of red, blue and green pigments having a particle diameter of not more than 1 μm in a photosensitive resin solution are applied onto a glass substrate, and then pixels are formed in a desired pattern by photolithography (see Japanese Patent Publication No. 4-37987, Japanese Patent Publication No. 4-39041).

Improvements in the color purity, color saturation and optical transmittance of color filters are being demanded, and hitherto, with an aim of improving the optical transmittance, a method has been adopted in which the content of the coloring pigment relative to the photosensitive resin in an image forming material is reduced, or the thickness of a pixel-forming film formed using the image forming material is reduced.

However, with such a method, the color saturation of the color filters themselves drops, and hence the display as a whole becomes whitish, with the vividness of color required for display being sacrificed; if, on the other hand, the color saturation is given priority and the content of the coloring pigment is increased, then the display as a whole becomes dark, and hence the amount of light from a backlight must be increased to secure sufficient brightness, and thus there is a problem of the energy consumption of the display being increased.

On the other hand, with an aim of improving the optical transmittance, a method is known in which the pigment particles are finely dispersed down to a particle diameter of less than half the wavelength of the color produced (see Kiyoshi Hashizume, Journal of the Japan Society of Color Material, December 1967, page 608), but with a blue pigment the wavelength of the color produced is shorter than with a red or green pigment, and hence in this case yet finer dispersion is required, and thus the cost is increased and stabilization after the dispersion becomes-a problem.

Furthermore, copper phthalocyanine blues having α, β and ε crystalline forms are widely used as blue pigments (see Shikizai Kogaku Handobukku (‘Color Material Engineering Handbook’), edited by the Japan Society of Color Material, page 333), but in the case of using a copper phthalocyanine blue alone as a blue pigment in color filters, the coloring power is low, and hence much pigment must be mixed in relative to the photosensitive resin to produce the desired color saturation, and there are outstanding issues with regard to thermal discoloration resistance after formation of the color filters and adhesion to a glass substrate, and moreover the amount of light transmitted at wavelengths above 600 nm is high, and hence there is a problem of the color purity dropping.

On the other hand, in the case of using ε copper phthalocyanine blue alone as a blue pigment, the amount added relative to the photosensitive resin can be reduced due to the excellent coloring power of ε copper phthalocyanine blue, but if the amount of the pigment mixed in is increased until the desired color saturation is obtained, then the light-blocking ability at 365 nm which is the wavelength for curing the photosensitive resin increases, and hence there is a problem that the photocuring sensitivity drops, causing decrease of thickness and pattern flow upon developing.

Moreover, β copper phthalocyanine blue is a greenish blue, and hence in the case of using this alone as a blue pigment, there is a problem of the deviation from the desired NTSC hue being large.

Moreover, the use in color filters of a pigment obtained by mixing a copper phthalocyanine blue with a dioxazine violet is known (see Japanese Patent Publication No. 6-95211, Japanese Patent Application Laid-open No. 1-200353, Japanese Patent Publication No. 4-37987, etc.), and if a mixed color of one of the above three copper phthalocyanine blues and I.C. Pigment Violet 23, which is a dioxazine violet, is used, then the transmission of light in a wavelength region of 500 to 550 nm can be suppressed, and hence the color purity-can be improved; however, there is a problem that the transmission of light in the desired blue region of 420 to 500 nm is suppressed, and hence the brightness of a display drops. Furthermore, in a display, the optical transmissivity in the blue region is cut down by a polarizer to 70 to 80% compared with for other color regions, and hence there are calls for an improvement in the amount of light transmitted by blue color filters.

It is an object of the invention to provide a blue color filter having a high transmissivity in the blue region but a low transmissivity in the green region, and an organic electroluminescent device having a good blue color purity.

### SUMMARY OF THE INVENTION

To attain the above object, in the invention, a blue color filter is made to contain a first colorant represented by structural formula (1) and a binder resin, and also contain a second colorant that absorbs fluorescence from the first colorant and does not have a fluorescence maximum in a visible wavelength region. 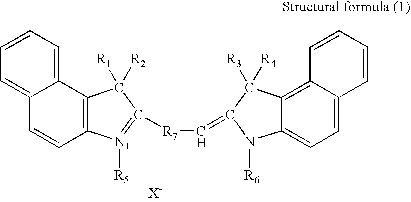
In structural formula (1), each of R₁ to R₆ independently represents an optionally substituted hydrogen atom, alkyl group, aryl group, or heterocyclic group, and R₇ represents a chain unsaturated hydrocarbon group having 1 to 6 carbon atoms. X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions.

By using a first colorant represented by structural formula (1) as a blue dye in the blue color filter as described above, the optical transmissivity over 500 to 600 nm can be suppressed, and hence the purity of the blue color can be improved, and moreover a blue color filter that transmits a large amount of light can be obtained. Moreover, by including, together with the first colorant, a second colorant that absorbs fluorescence from the first colorant and does not have a fluorescence maximum in a visible wavelength region, i.e. not more than 750 nm, fluorescence in a wavelength region of 600 to 700 nm produced by the first colorant can be absorbed by the second colorant, and hence a drop in the purity of the blue color can be prevented.

Moreover, in the invention, a blue color filter is made to contain a first colorant represented by structural formula (1) and a binder resin, and also contain a second colorant represented by structural formula (2). 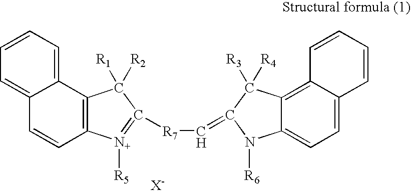
In structural formula (1), each of R₁ to R₆ independently represents an optionally substituted hydrogen atom, alkyl group, aryl group, or heterocyclic group, and R₇ represents a chain unsaturated hydrocarbon group having 1 to 6 carbon atoms. X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions. 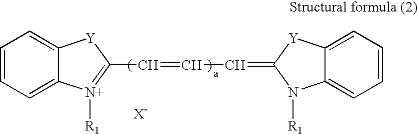
In structural formula (2), R₁ represents a hydrogen atom, an alkyl group, an aryl group, or a heterocyclic group. X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions. Y represents an oxygen atom or a sulfur atom. a represents an integer from 1 to 6.

Furthermore, the blue color filter of the invention may be made to contain a quencher anion that quenches fluorescence from the first or second colorant.

Moreover, an organic electroluminescent device according to the invention uses a blue color filter as above as at least some of the color filters thereof.

### BRIEF DESCRIPTION OF THE DRAWINGS

FIG. 1 is a schematic sectional view of an organic EL device having blue color filters of the invention.

### DETAILED DESCRIPTION OF THE PREFERRED EMBODIMENTS

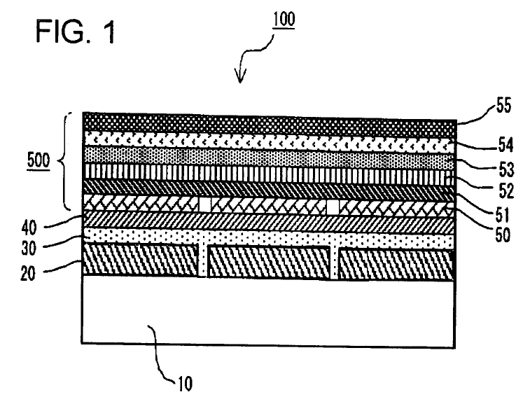

As shown in FIG. 1, with an organic EL device 100 of the present embodiment, blue color filters 20, an organic protective layer 30, an inorganic oxide film 40, transparent anodes 50, a hole injection layer 51, a hole transport layer 52, a light-emitting layer 53, an electron injection layer 54, and cathodes 55 are formed in this order on a transparent supporting substrate 10, with the whole constituting the organic EL device 100.

Next, a description will be given of materials used in preparing a blue pixel forming material for forming the blue color filters 20 in the invention.

First Colorant

A blue color filter of the invention contains a cyanine type colorant represented by structural formula (1) as a first colorant. One colorant represented by structural formula (1) may be used alone, or a plurality may be used in combination. A cyanine type colorant represented by structural formula (1) has high chemical and thermal stability itself, and hence the heat resistance of the blue color filter will be high even if a pigment dispersion method is not used. Furthermore, another blue pigment of a copper phthalocyanine type or the like may be used mixed with the first colorant.

With the invention, when obtaining the blue image forming material, the mixing proportion of the cyanine type colorant represented by structural formula (1) relative to a binder resin is preferably 0.1 to 40 parts by weight. As a result, transmission of light in a wavelength region of 500 to 550 nm can be suppressed, and hence the color purity can be improved. Moreover, the cyanine type colorant represented by structural formula (1) may be used after having been made into a pigment, in which case a publicly known method can be used as the method of manufacturing the blue pigment dispersion. For example, a blue pigment dispersion containing a copper phthalocyanine blue and a cyanine type colorant represented by structural formula (1) may be obtained by subjecting the copper phthalocyanine blue and the cyanine type colorant represented by structural formula (1), together with an organic solvent, a pigment derivative for dispersion stabilization (added if necessary) and a dispersant, to fine dispersion of the pigment and stabilization using a disperser such as a sand mill.

Second Colorant

A colorant that absorbs fluorescence from the first colorant (600 to 700 nm) and does not have fluorescence maximum in the visible wavelength region (750 nm or below) is added as a second colorant. The mixing proportion of the second colorant relative to the binder resin is preferably 0.1 to 40 parts by weight. Moreover, to enable functioning as a blue color filter, a colorant that does not absorb in the blue wavelength region is preferable. Specifically, a colorant for which the transmissivity at 450 nm is at least 60% when added to the filter can be used.

Examples include 1,1′-diethyl-4,4′-carbocyanine iodide (cryptocyanine), 1,1′-diethyl-2,2′-dicarbocyanine iodide (DDI), 3,3′-dimethyloxatricarbocyanine iodide (methyl-DOTCI), 1,1′,3,3,3′,3′-hexamethylindotricarbocyanine iodide (HITCI), IR125 (made by Lambda Physik), IR144 (made by Lambda Physik), 3,3′-diethyl-9,11-neopentylenethiatricarbocyanine iodide (DNTTCI),1,1′,3,3,3′,3′-hexamethyl-4,4′,5,5′-dibenzo-2,2′-indotricarbocyanine iodide (HDITCI), and 1,2′-diethyl-4,4′-dicarbocyanine iodide (DDCI-4).

Moreover, as the second colorant, a cyanine type colorant represented by structural formula (2) may be used, with specific examples including 3,3′-diethylthiatricarbocyanine iodide (DTTCI) and 3,3′-diethyl-4,4′,5,5′-dibenzothiatricarbocyanine iodide (DDTTCI). 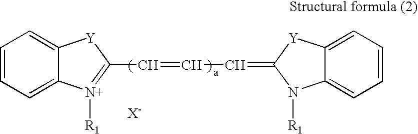
In structural formula (2), R₁ represents a hydrogen atom, an alkyl group, an aryl group, or a heterocyclic group. X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions. Y represents an oxygen atom or a sulfur atom. a represents an integer from 1 to 6.
Quencher

The colorants used are cationic colorants, and hence, for example, an anionic singlet oxygen quencher can be used as a quencher. Specifically, transition metal chelates, bis-iminium salts and so on as disclosed in Japanese Patent Application Laid-open No. 59-55795, Japanese Patent Application Laid-open No. 60-234892 and so on can be used.

Binder

The binder resin used in the blue color filter of the invention is preferably transparent to visible light, and preferably has good adhesion to the substrate; a publicly known thermoplastic resin, thermosetting resin, photocurable resin or the like can be used. A photosensitive resin is particularly preferable, since then a fine pattern of filters can easily be formed.

Manufacture of Blue Color Filters and Organic EL Device

The blue color filter 20 are formed by applying a blue image forming material comprising materials as described above in a desired pattern on the transparent supporting substrate 10. There are no particular limitations on the application method, with it being possible to use an ordinary spin coating method, roll coating method, casting method, screen printing method, ink jet method or the like. There are also no particular limitations on the curing method, with it being possible to use heat curing (considering degradation of the fluorescent materials, curing at a temperature of not more than approximately 150° C. is preferable), moisture curing, chemical curing, photocuring (considering degradation of the fluorescent materials, curing with visible light is preferable), a curing method combining the above, or the like.

Before or after forming the blue pixels, red and/or green color filters may be formed as required using red and/or green pixel forming materials, whereby color filters of a plurality of colors can be formed. Furthermore, by forming an organic light emitter 500 on the color filters with an organic protective layer 30 and an inorganic oxide film 40 therebetween, a multi-color organic EL device can be manufactured. Methods of forming the organic light emitter 500 include a method in which transparent anodes 50, a hole injection layer 51, a hole transport layer 52, a light-emitting layer 53, an electron injection layer 54 and cathodes 55 are successively formed on the color filters, and a method in which an organic light emitter 500 formed on a separate substrate is stuck onto the inorganic oxide film 40. The organic EL device 100 manufactured in this way can be applied to either a passive driving type organic EL display or an active driving type organic EL display.

Examples are given below.

### EXAMPLE 1

Formation of Black Mask

Although not shown in FIG. 1, to eliminate the effects of reflected light at edges of the blue color filters 20 and the transparent electrodes 50 when evaluating the contrast, first a black mask was provided with an objective of making it such that the edges of the blue color filters 20 could not be seen from the surface of the transparent supporting substrate 10.

A black mask coating liquid (CK8400L, made by Fujifilm Arch Co., Ltd.) was applied over the whole surface of a glass transparent supporting substrate 10 using a spin coating method, drying was carried out by heating at 80° C., and then using a photolithography method, a black mask pattern of stripes with a pitch of 0.13 mm and gaps of 0.10 mm was obtained.

Formation of Blue Color Filters

Using a transparent photopolymerizable resin (259PAP5 made by Nippon Steel Chemical Co., Ltd.) as a binder, 2 parts by weight of a colorant represented by structural formula (3) as a blue dye was added to 100 parts by weight in terms of solids of the transparent photopolymerizable resin, and 1 part by weight of a second colorant represented by structural formula (4) (HDITCI made by Lambda Physik) was further added, thus obtaining a blue color filter coating liquid.

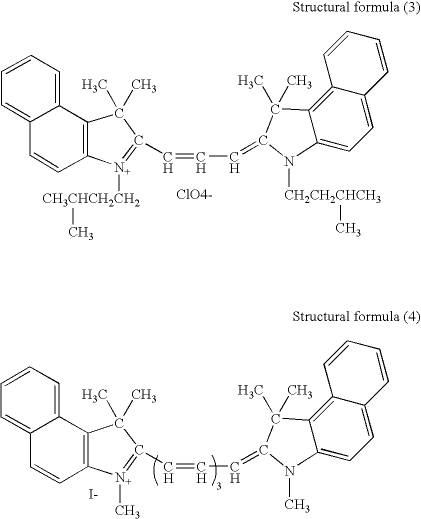

The blue color filter coating liquid was applied onto the transparent supporting substrate 10 using a spin coating method, drying was carried out by heating at 80° C., and then using a photolithography method, a blue color filter pattern of stripes with a pitch of 0.13 mm and gaps of 0.01 mm was formed.

Formation of Organic EL Device

After the blue color filters 20 had been formed on one main surface of the glass transparent supporting substrate 10 using the above method, an organic protective layer 30 and an inorganic oxide layer 40 were deposited thereon in this order, and then an organic light emitter 500 was formed thereon, thus manufacturing an organic EL device 100. The organic light emitter 500 was constituted from six layers comprising transparent anodes 50, a hole injection layer 51, a hole transport layer 52, a light emitting layer 53, an electron injection layer 54, and cathodes 55. The specific manufacturing procedure is described below.

A transparent photopolymerizable resin (259PAP5 made by Nippon Steel Chemical Co., Ltd.) was applied onto the transparent supporting substrate 10 on which the blue color filters 20 had been formed, and drying was carried out, thus forming an organic protective layer 30 of thickness 5 μm on the blue color filters 20, and then an inorganic oxide layer 40 of thickness 100 nm made of SiO₂ was formed thereon by sputtering. A layer made of ITO was then deposited over the whole of the inorganic oxide layer 40 by sputtering, and transparent anodes 50 were obtained by carrying out patterning as follows. That is, a resist agent (OFRP-800 made by Tokyo Ohka Kogyo Co., Ltd.) was applied to a thickness of 100 nm onto the ITO film, and then transparent anodes 50 having a striped pattern with a line pitch of 0.13 mm and gaps of 0.01 mm were obtained using photolithography.

Next, the substrate was put into a resistive heating vapor deposition apparatus, and a hole injection layer 51, a hole transport layer 52, a light-emitting layer 53, an electron injection layer 54 and cathodes 55 were deposited in this order without releasing the vacuum. During the deposition, the pressure inside the vacuum chamber was reduced down to 1×10⁻⁴ Pa. Specifically, the hole injection layer 51 was made to be a copper phthalocyanine (CuPc) layer of thickness 100 nm, the hole transport layer 52 was made to be a 4,4′-bis[N-(1-naphthyl)-N-phenylamino]biphenyl (α-NPD) layer of thickness 20 nm, the light-emitting layer 53 was made to be a 4,4′-bis(2,2′-diphenylvinyl)biphenyl (DPVBi) layer of thickness 30 nm, and the electron injection layer 54 was made to be a tris(8-hydroxyquinoline) aluminum complex (Alq) layer of thickness 20 nm. Moreover, the cathodes were made to be Mg/Ag (weight ratio 1:10) of thickness 20 nm, and were formed in a striped pattern with a pitch of 0.33 mm and gaps of 0.05 mm perpendicular to the anode lines using masked vapor deposition.

After the deposition of the various layers described above had been completed, the organic EL device 100 was taken out from the vapor deposition apparatus, and was sealed using sealing glass and a UV adhesive under a nitrogen atmosphere without being allowed to come into direct contact with atmospheric air (not shown in the drawing). The organic EL device 100 manufactured emitted blue light having a peak at a wavelength of 470 nm.

### EXAMPLE 2

An organic EL device was manufactured as in Example 1, except that when forming the blue color filters, a colorant represented by structural formula (5) was used as a second colorant instead of the second colorant used in Example 1, with 1 part by weight being added per 100 parts by weight in terms of solids of the transparent photopolymerizable resin.

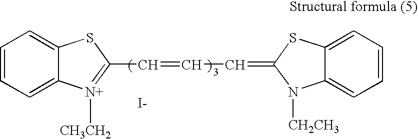

### EXAMPLE 3

A blue color filter coating liquid was prepared and an organic EL device was obtained as in Example 2, except that when forming the blue color filters, a nickel complex represented by structural formula (6) was added as a quencher in a proportion of 0.3 mol per 1 mol of the first colorant.

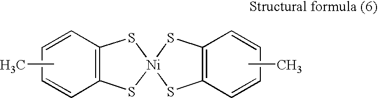

### COMPARATIVE EXAMPLE 1

A blue color filter coating liquid was prepared as in Example 1, except that a copper phthalocyanine blue was used as a pigment instead of the first colorant and the second colorant used in Example 1. The amount added of the pigment was made to be such that the optical transmissivity at a wavelength of 470 nm was the same as in Example 1 when the blue color filters were formed to the same thickness as in Example 1.

(Evaluation)

The following evaluation was carried out for each of the manufactured samples. The evaluation results are shown in Table 1. Here, for the CIE chromaticity, each manufactured device was made to emit light and the chromaticity was evaluated. A color meter (MCPD-1000 made by Otsuka Electronics Co., Ltd.) was used in the measurements. For the contrast, a comparison was carried out of the contrast for the case of irradiating light from a fluorescent lamp (1000 1×) onto the display surface of each device from an angle of 45° C. The values in the table are relative values taking the result for the comparative example to be 1.0; if the value is greater than 1.0, then the contrast is improved. For the transmissivity, the absorption spectrum was obtained using an absorptiometer (UV-2100PC made by Shimadzu Corporation), and a comparison was made of the light transmissivities at wavelengths of 470 nm and 510 nm.

Table 1

| | | | | Comparative |
|---|---|---|---|---|
| | Example 1 | Example 2 | Example 3 | Example 1 |
| (1) CIE | 0.12, 0.09 | 0.12, 0.10 | 0.13, 0.10 | 0.16, 0.18 |
| chromaticity (x, y) | | | | |
| (2) Contrast | 1.4 | 1.4 | 1.6 | 1.0 |
| (3) Transmissivity | 85% | 85% | 85% | 85% |
| (470 nm) | | | | |
| (510 nm) | 50% | 48% | 46% | 60% |

As shown in Table 1, in the case of forming the films so as to have the same optical transmissivity at 470 nm, the optical transmissivity at 510 nm is lower for the examples than for the comparative example. This means that the light-blocking ability in a wavelength region that would lower the purity of the blue color is higher for the color filters of the examples than for the color filters of the comparative example. Moreover, with the color filters of the comparative example in which a pigment was dispersed in a binder, scattering is prone to occurring in the color filters and at interfaces. On the other hand, with the color filters of the examples, it is thought that the contrast exhibits a high value because the colorants are completely dissolved in the binder and hence the transparency is high.

According to the invention, there can be provided a blue color filter suitable for an organic EL display for which the purity of the blue color and the transmissivity are high and also the contrast is good, and an organic EL device using this blue color filter.

1-4. (canceled)

5. A blue color filter, comprising:
a first colorant represented by the following structural formula (1); 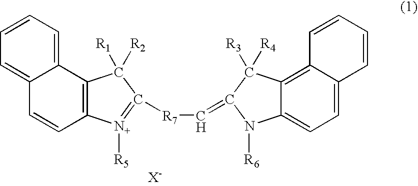
a binder resin; and
a second colorant that absorbs fluorescence from the first colorant and does not have a fluorescence maximum in a visible wavelength region;
wherein, in structural formula (1), each of R₁ to R₆ independently represents an optionally substituted hydrogen atom, alkyl group, aryl group, or heterocyclic group, and R₇ represents a chain unsaturated hydrocarbon group having 1 to 6 carbon atoms; and X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions.

6. An organic electroluminescent device comprising:
an organic light emitter; and color filters;
wherein the light emitter and the color filters are laminated, and
wherein at least some of the color filters comprise the blue color filter according to claim 5.

7. The blue color filter according to claim 5, comprising a quencher anion that quenches fluorescence from the first colorant or the second colorant.

8. An organic electroluminescent device comprising:
an organic light emitter; and color filters;
wherein the light emitter and the color filters are laminated, and
wherein at least some of the color filters comprise the blue color filter according to claim 7.

9. A blue color filter, comprising:
a first colorant represented by the following structural formula (1) 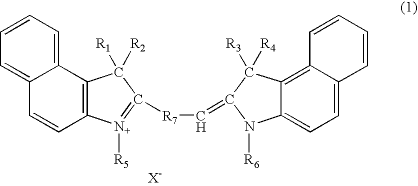
a binder resin; and
a second colorant represented by the following structural formula (2) 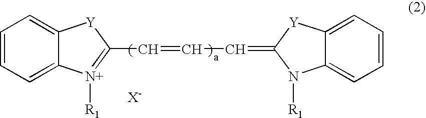
wherein, in structural formula (1), each of R₁ to R₆ independently represents an optionally substituted hydrogen atom, alkyl group, aryl group, or heterocyclic group, and R₇ represents a chain unsaturated hydrocarbon group having 1 to 6 carbon atoms; and X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions; and
wherein, in structural formula (2), R₁ represents a hydrogen atom, an alkyl group, an aryl group, or a heterocyclic group; X⁻ represents an anion selected from the group consisting of I⁻, Br⁻, Cl⁻, F⁻, ClO₃⁻, BrO₃⁻, IO₃⁻, ClO₄⁻, BF₄⁻, PF₄⁻, SbF₄⁻, BrO₄⁻, and organic anions; Y represents an oxygen atom or a sulfur atom; and a represents an integer from 1 to 6.

10. An organic electroluminescent device comprising:
an organic light emitter; and color filters;
wherein the light emitter and the color filters are laminated, and
wherein at least some of the color filters comprise the blue color filter according to claim 5.

11. The blue color filter according to claim 5, comprising a quencher anion that quenches fluorescence from the first colorant or the second colorant.

12. An organic electroluminescent device comprising:
an organic light emitter; and color filters;
wherein the light emitter and the color filters are laminated, and
wherein at least some of the color filters comprise the blue color filter according to claim 7.
